(19) United States
(12) Patent Application Publication
(10) Pub. No.: US 2026/0358413 A1
(43) Pub. Date: Nov. 12, 2026

(54) TEST PATTERN VECTORS IN HOMOGENOUS MULTI-DIE PACKAGES

(71) Applicant: KANDOU LABS SA, Saint-Sulpice (CH)

(72) Inventors: Ravindra Nayudu, Plan-les-Ouates (CH); Yassine Fkih, Lausanne (CH)

(21) Appl. No.: 19/134,505

(22) PCT Filed: Nov. 30, 2023
(86) PCT No.: PCT/US2023/081815

§ 371 Date: May 30, 2025

Related U.S. Application Data
(60) Provisional application No. 63/385,572, filed on Nov. 30, 2022.

(51) Int. Cl. G01R 31/3185; G01R 31/319

(52) U.S. Cl. CPC G01R 31/318513; G01R 31/318536; G01R 31/318594; G01R 31/31908

(57) ABSTRACT

Connecting test equipment to an input pin of the MCM, transmitting pipeline delay configuration data for a first die-under-test (DUT) to configure a first die input pipeline register with a first delay value at a first die of the MCM, transmitting ATP data into a first die scan chain register in a predetermined number of clock cycles via the first delay value of the first die input pipeline register, configuring the first die to perform a scan chain test with the ATP datal, transmitting pipeline delay configuration data for a second DUT to configure the first die input pipeline register with a second delay value, transmitting the ATP data into a second die scan chain register in the predetermined number of clock cycles via the reconfigured first die input pipeline register and a die-to-die interconnect, and configuring the second die to perform a scan chain test with the ATP data.

### CROSS-REFERENCE TO RELATED APPLICATIONS

This application claims the benefit of U.S. Application No. 63/385,572, filed Nov. 30, 2022, entitled “TEST PATTERN VECTORS IN HOMOGENOUS MULTI-DIE PACKAGES”, which is hereby incorporated herein by reference in its entirety for all purposes.

### FIELD OF THE INVENTION

One or more embodiments disclosed relate to testing integrated circuits (ICs), and more particularly, to Inter-Chip scan testing with data delivery to homogenous dies using one or more pipelines configured to enable vector depth and test time optimization.

### BACKGROUND

Semiconductor integrated circuits (ICs) are manufactured using a multi-phase process, packaging generally refers to the process of mounting or placing dies (i.e., “tiles” as referred to herein) within plastic, ceramic, or other packages that facilitate use of multiple tiles packaged in a device. Normally each die is individually tested since the packaged device has heterogenous dies.

Typically, ICs are characterized in terms of performance. Performance can be measured in terms of whether the IC is able to perform within established design requirements relating to operating frequency, signal fidelity, signal response, or the like. Performance analysis identifies ICs that do not meet minimum design requirements. ICs include sequences of combinatorial logic that are made up of thousands of logic gates, latches, and the like. Scan chain tests are utilized to load the combinatorial logic gates with a known automated test pattern (ATP), the outputs of which are analyzed against known results to determine if one or more faults exist within the combinatorial logic. Faults in an IC may include one or more of stuck-at faults, transistor faults, bridging faults, open faults, delay faults, and the like.

Test costs are influenced by volume of the patterns (i.e., vector depth) to store in tester memory, speed of shift-in/out of bits through scan chains (i.e., flip-flops), i.e., shift clock frequency. ATE (Automatic Test Equipment) works on a cycle accurate manner (e.g., 10 ns) fixed cycles, with all the inputs driven with respect to clock cycles. At the same time, response from the device is monitored (i.e., strobing) on outputs; output is always monitored with latency interims of cycles, that depends on scan chain length. Electronic Design Automation (EDA) tools accordingly generate patterns with Automatic Test Pattern Generation (ATPG) enabling test scans.

### BRIEF SUMMARY

Embodiments are described here for accessing and testing inner tiles (or dies) within packaged multi-chip-module (MCM) devices that have limited input/output (I/O) for use by testing equipment, where all the tiles are interconnected on package substrate to reduce costs with compliant specifications. Costs associated with production tests involve storage capacity for storing test vectors in addition to the duration for which the test equipment is in use. Emboidments described herein address ATPG Scan Pattern vector depth by reusing the same pattern set to test all tiles (or same dies), which reduces the amount of memory required to save the test patterns. Further, by using scan chain latches between the dies of a multi-die MCM, a higher ATPG scan shift mode frequency may be used, which reduces total test time of testing all tiles during production of packaged device with multiple tiles. Dynamically configuring scan chain pipeline registers among the serially-connected homogenous dies allows the reuse of the same pattern set irrespective of which die is under test, thereby saving vector memory depth, which in turn lowers the packaged device test costs in production. Similarly, configurable scan chain pipeline registers allow an increased ATPG shift mode frequency (i.e., higher frequency, a shorter time-period), to reduce the actual time spent and thereby reduce the associated device test costs in production to test each device.

Briefly summarized, the MCM system architecture and inter-chip selective test vector scanning methodology of homogenous dies packaged in MCM devices is employed using limited accessible pins in combination with reconfigurable input scan chain pipeline registers. A die-to-die interconnect with wire pass-throughs are used to select inter-die channels between each of the dies. Automated test pattern (ATP) testing vectors are loaded to scan chains of each circuit die throughout the MCM with the same ATP data and timing constraints by configuring a predetermined number of clock cycles via a delay value adjustment of the reconfigurable input pipeline registers, and the die-to-die interconnect. A described testing method configures a first die input pipeline register with a first delay value at a first die of the MCM. ATP data is loaded into a first die scan chain register in a predetermined number of clock cycles via the first delay value of the first die pipeline register, and a scan chain test of the first die is performed with the ATP data. The first die input pipeline register is reconfigured with a second delay value, and the ATP data is loaded into the second die scan chain register in the predetermined number of clock cycles via the second delay value of the first die pipeline register and the die-to-die interconnect, and a scan chain test of the second die is performed. The described method is further extensible to three, four, or more, homogenous dies.

### BRIEF DESCRIPTION OF THE DRAWINGS

Various embodiments in accordance with the present disclosure will be described with reference to the drawings. Same numbers are used throughout the disclosure and figures to reference like components and features.

FIG. 1 is a block diagram illustrating homogenous dies in a multi-chip-module (MCM) package, for n- dies/tiles of a multiplicity of n dies having at least one associated reconfigurable pipeline in stage of a multi-die integrated circuit (IC) structure in accordance with an embodiment of the present inventions.

FIG. 2 shows the Pipeline In/Out package connections from interconnect dies for Flip-Flop (FF) scan chain in a network illustrating single die, i.e., central block scan chains of a single die of a multi-die IC structure in accordance with the first die (tile) of the FIG. 1 block diagram having homogenous Dies in a package thereof.

FIG. 3 provides a reconfigurable Inputs Stage for Pipeline Scan Data of a multi-die IC structure to the FF scan chain network of FIG. 2 in accordance with each of the tiles of the FIG. 1 package in accordance with the disclosed embodiments.

FIG. 4 shows the FF Scan Chains for ATPG test digital logic of each IC device of the multi-tile homogeneous structure of the FIG. 1 having homogenous dies in accordance with each of the tiles of the package.

FIG. 5 provides a reconfigurable Pipeline Output Stage for the Scan Data of a multi-die IC structure in accordance with the disclosed embodiments.

FIGS. 6A and 6B are a plurality of dies having at least one reconfigurable pipeline in stage associated in a simplified fashion with two (2) identical dies showing channel routing on substrate with pipeline FFs in Scan-In/Out paths the two interconnect dies for the scan chain network IC of a two-die MCM structure thereof.

FIG. 7 illustrates 1st-die testing of the two (2) identical dies showing channel routing on substrate arrow-highlighted data path targeting scan chain in 1st die of a two-die MCM structure in accordance with the present embodiments.

FIG. 8 illustrates 2nd-die testing of the two (2) identical dies showing channel routing on substrate arrow-highlighted data path targeting scan chain in 2nd die of the two-die MCM structure thereof.

### DETAILED DESCRIPTION

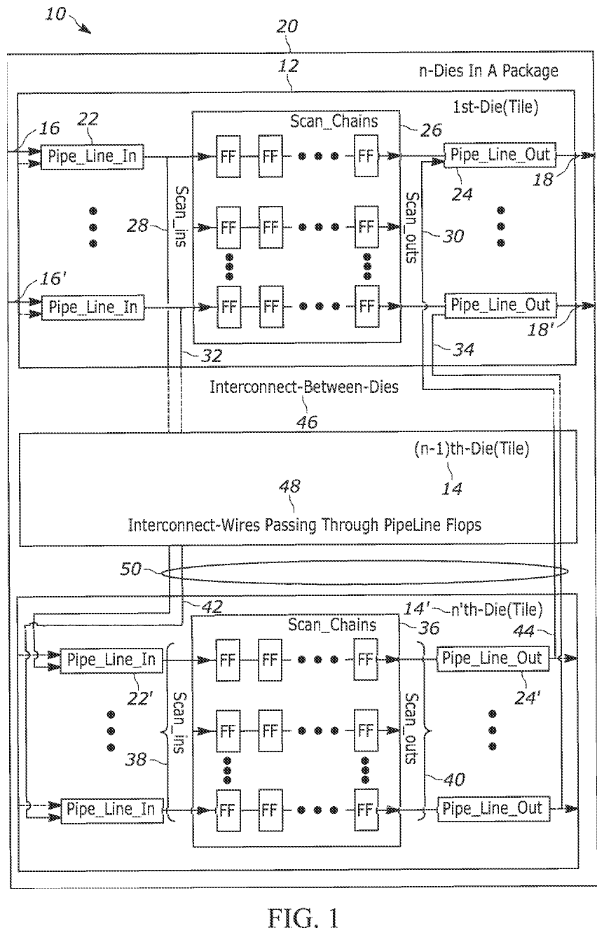

FIG. 1 is a block diagram illustrating a selective test vector scanning embodiment for packaged dies of multi-chip-module (MCM) devices, herein multi-die integrated circuit (IC) MCM structure 10. In some embodiments, a MCM may have limited accessible input/output (I/O) pins, and may thereby use reconfigurable input pipeline registers for n-dies/tiles of a plurality of dies, including a first die 12, and a second die 14. The MCM may include at least one associated reconfigurable input pipeline register 22. Embodiments described herein specifically refer to a plurality of homogenous circuit dies, however, such a constraint should not be considered limiting. The MCM of FIG. 1 further includes a die-to-die interconnect between each of the dies, which may re-purposed from e.g., serial peripheral interface (SPI) applications to convey automated test pattern (ATP) testing vectors. Each circuit die includes a scan chain register, and the ATP testing vectors are loaded to the scan chain registers of selected homogenous dies with the same ATP data and timing provided to the MCM by configuring the reconfigurable input pipeline registers of the respective dies with a specific number of clock cycles via a delay value adjustment to account for delays introduced by the die-to-die interconnect. Homogenous dies use the same ATP data loaded to die scan chains with a defined timing pattern, where each die scan chain can be properly loaded within the same predetermined number of clock cycles, regardless of the particular die location within the set of serially-connected homogenous dies. The plurality of circuit dies may be arranged in a serially-connected hierarchical structure. That is to say, when loading the scan chain register in a selected die, the ATP data is conveyed from an input pipeline register of a first circuit die, over the die-to-die interconnect to an input pipeline register of a second circuit die, and possibly via another die-to-die interconnect to a third circuit die. At least one output pin IC package connection from the MCM connects a die scan out coupling of the multiplicity of dies to a reconfigurable output pipeline register. The MCM structure 10 limited accessible pins may be re-purposed pins for testing.

The FIG. 1 block diagram employs n-homogenous circuit dies of the hierarchical MCM structure 10 according to the present described embodiment. An IC package 20 includes a multiplicity of n dies within the IC package 20, each of dies 12, 14 having at least one associated reconfigurable input pipeline register 22 configured to provide a die scan_in coupling 28 to at least one die scan-chain 26. Each of dies 12, 14 further include at least one reconfigurable output pipeline register 24 from a die scan_out coupling 30. At least one input pin IC package connection 16 is provided for loading ATP scan data into the IC package 20 via the reconfigurable input pipeline register 22. The input pin IC package connection 16 may load the ATP scan data into the input pipeline register 22 of a leader circuit die, e.g., tile 12, by default. The input pipeline register 22 of the leader circuit die 12 may be selectably configured to couple the ATP scan data into the scan chain 26 on the leader die, or to reroute the ATP scan data over a die-to-die interconnect to follower circuit die 14 to be leaded into the scan chain 36.

At least one output pin IC package connection 18 is provided from the IC package 20 for outputting the results of the scan chain test, i.e., the captured state of the combinatorial logic after having the scan data loaded. As shown, the output pin IC package connection 18 is connected to the die scan_out couplings 30, 34 of one of the multiplicity of n dies via a reconfigurable output pipeline register 34 for selectively communicating the die scan_out coupling 30 from a selected one of the multiplicity of n dies. A die-to-die interconnect 46 having wire pass-throughs 48 establishes a plurality of inter-die channels 50 between each of the plurality of dies 12, 14 within the IC package 20.

In some embodiments, the input pipeline register 22 includes multiplexing logic for selectively routing inbound ATP scan data received via input pin 16 to the scan chain 26 within the leader circuit die 12 or to input pipeline registers of a second circuit die of the n homogenous circuit dies. Similarly, multiplexing logic in the output pipeline register 24 may be utilized to selectively output the scan chain results from one of the n homogenous circuit dies, i.e., the scan chain 26 within the leader circuit die 12 or scan chain results 30 received via the die-to-die interconnect 46. An integrated circuit (IC) structure can include an interposer including a plurality of inter-die wires and a first die coupled to the interposer. The first die can include a first output including a first flip-flop coupled to a first inter-die wire of the plurality of inter-die wires and a first input including a second flip-flop coupled to a second inter-die wire of the plurality of inter-die wires. The IC may include existing inter-die substrate connections for, e.g., tile-to-tile serial peripheral interface (SPI) communications. Such an inter-die data interface may be re-utilized for the purpose of Scan In/Out data access. Based on the above hardware structures in place, the IC may be configured (i.e., dynamically through device initialization sequence) to apply the ATPG pattern set to the active tile under test. In some embodiments, the configuration of tiles includes how many stages of the pipelines to enable in each tile based on the spread between tiles before applying the ATPG patterns to the tile under test. Latches within each input pipeline register 22 for the follower tiles are configured to latch the ATPG patterns received over the die-to-die interconnect to protect the data against the clock-skew.

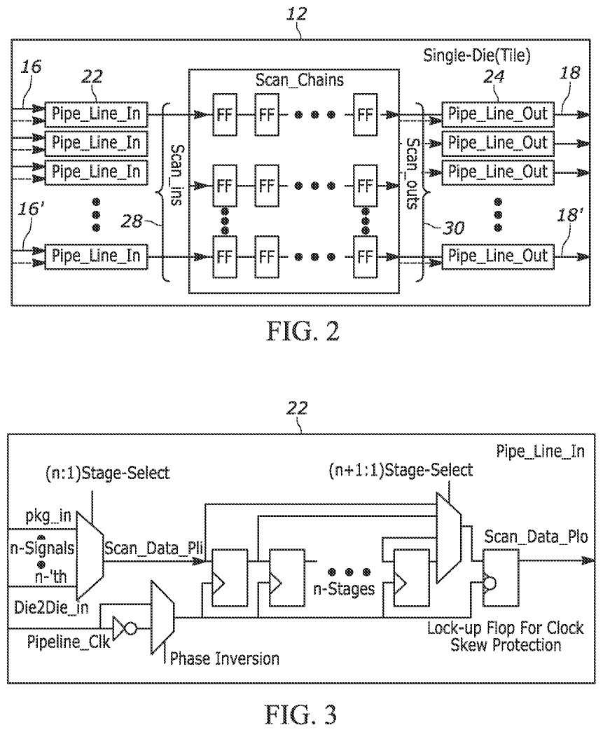

FIG. 2 is a block diagram of circuit die 12, in accordance with some embodiments. As shown, the input and output pipeline register package connections are shown from interconnect dies for Flip-Flop (FF) Scan Chains 26 of the single first die 12 of homogenous dies 12, 14. The scan chains are loaded via the reconfigurable input pipeline register 22 associated with the one or more input pins 16, 16′. FIG. 3 is a schematic for a reconfigurable input pipeline register 22, in accordance with some embodiments. As shown, multiple input pipeline registers 22 associated with input pins 16, 16′ of FIGS. 2 and 3 may be configured in parallel for each homogenous die if multiple input pins are available, but such a constraint should not be considered limiting. As shown, each input pipeline register 22 includes a sequence of flip-flops, each flip-flop having a respective output tap. The flip-flops are configured to apply a configurable delay to the ATP scan data. The input pipeline register 22 further include a multiplexer having a plurality of inputs, each input connected to a respective output tap of the sequence of flip-flops. The multiplexer is configured to receive a select signal, and to select one output tap of the plurality of output taps of the sequence of flip-flops to apply a configurable delay value to the ATP scan data. The delay value selected by the multiplexer may be associated with which homogenous die of the multiplicity of homogenous dies is under test. When circuit dies further down in the hierarchy are under test, the ATP test signal is conveyed through a chain of input pipeline registers. As described above, each input pipeline register includes multiple flip-flop circuits that incrementally progress the ATP test signal. Utilizing a sequence of flip-flop circuits from the input pin to the scan-chain input of the circuit die under test breaks up what would otherwise be a long signal path with a long propagation delay (and thus a slower shift clock rate) into a larger number of smaller paths with small individual propagation delays. As the shift clock rate is dependent on the longest propagation delay, minimizing the maximum propagation delay thus reduces the shift clock rate, which accelerates the scan chain test itself as the scan chain and loading of input pipeline registers is performed using the same clock signal. The die level JTAG IEEE 1149.1 (Joint Test Action Group) standard defines test logic included in the MCM 10 circuit to provide a standardized serial bus test clock signal. In accordance with the JTAG test standard, the clock scan shift frequency may be accelerated to reduce test time. In some alternative embodiments, the clock signal may be supplied directly as routed directly die to die.

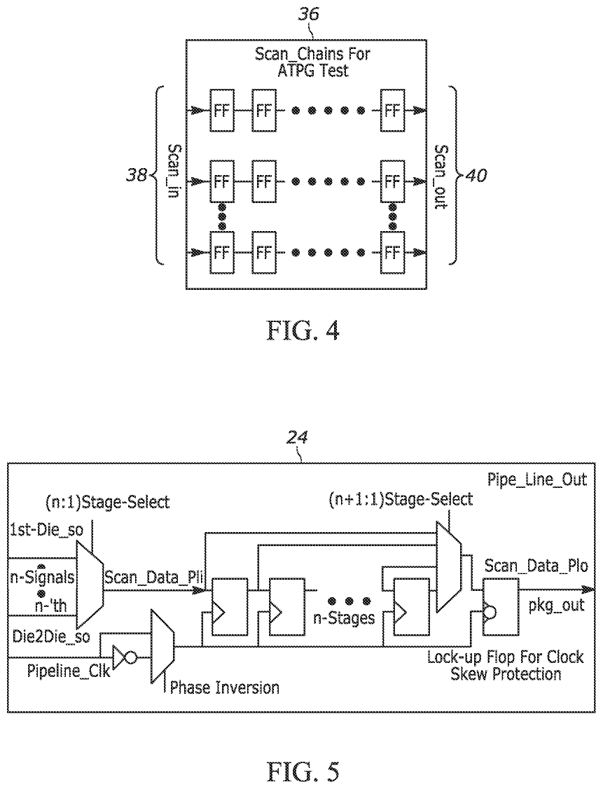

FIG. 4 shows the FF Scan Chains for testing digital logic of each die of the MCM structure 10, in accordance with some embodiments. As shown, each scan-chain includes a sequence of flip-flops. The flip-flops are serially loaded with ATP scan data in a predetermined number of clock cycles in a shift-register manner as described above. The ATP scan data is loaded in parallel to combinatorial logic (not shown) of the MCM and processed via the combinatorial logic using a single clock cycle. The outputs of the combinatorial logic are latched into the scan-chain flops and shifted out at the scan_out port 40 for analysis. Multiplexed Scan Style is the industry Standard way of testing Digital circuits for manufacturing defects in Production. Manufacturing defects can be Stuck-At faults where any Standard Cell (like Flop, logic gate) can be Stuck-to GND or Supply during Manufacturing process. Defects can also be due to RC variation of the metals which influence transition of the signal from one state to another. Putting pipeline registers in each die, then as soon as the bit is latched in FF1 of die #1, then changing the signal to the next bit, one can accept the test pattern bit sequence at a faster rate by having these pipeline registers in each die. The increase in frequency of loading serially connected dies is a helpful byproduct of using the pipeline registers.

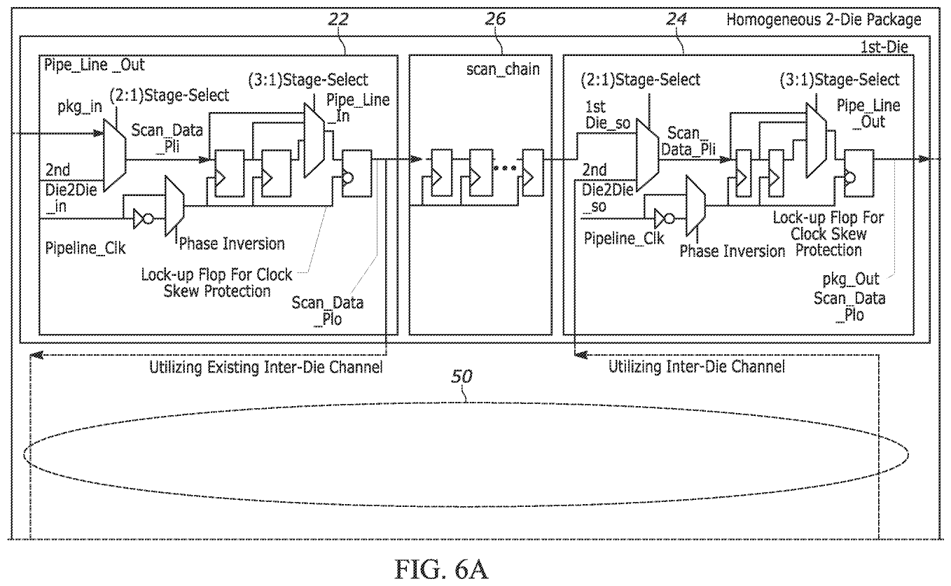

FIG. 5 is a schematic of a reconfigurable output pipeline register 24 for the scan data of MCM 10, in accordance with some embodiments. Each homogenous circuit die includes output pipeline register 24 as shown. The processed scan chain data is propagated through each circuit die in the circuit die hierarchy according to delay values similar to the delay values used by the input pipeline registers 22 to load the scan data into the scan chain. For example, if the leader circuit die 12 is currently under test, the output pipeline register 24 of the leader tile is the only output stage in use, and the delay value may be at a highest setting. As circuit dies 14 further down the chain are selected to be the current die under test, the processed scan chain data still progresses through the output pipeline registers 24 of the circuit dies higher up in the circuit die hierarchy. The amount of delay applied by each output pipeline register 24 may decrease proportionally to how many circuit dies are in the overall hierarchy with respect to the current die under test. With the example herein, a Design for Test (DFT) testing of MCM structure 10 multi-die ICs is achieved for multiple homogenous dies within an IC package with the ATPG targeted die testing. DFT testing allows for selecting from a plurality of different available outputs from the input and output pipeline registers to adjust the pipeline registers with a configurable delay value as a way of programming the delay of the first die pipeline register to route the ATP sequence data to a second die in the hierarchy. When testing the second circuit die in the hierarchy, pipeline configuration information is transmitted into the MCM via the input pin to configure the first die input pipeline register 22 with a reduced delay value to account for the delay incurred by propagating the die-to-die interconnect. In such an embodiment, the ATP sequency data is loaded into the scan chain of the second die in the same predetermined number of clock cycles in which the ATP scan data is loaded into the scan chain of the first circuit die in the hierarchy. Similarly, the pipeline configuration information transmitted to the MCM via the input pin configures the first die output pipeline register 24 of the first circuit die with a reduced delay value to compensate for the scan chain results from the second circuit die traversing the die-to-die interconnect.

The actual measure of time that is determined can be compared with an expected measure of time to determine whether any defects may exist within the DUT and, for example, within the inter-die wires or connections between inter-die wires and the dies. The die-to-die interconnect between the first die and the second die of the MCM 10 loads the ATP data into the second die scan chain register in the same predetermined number of clock cycles as when the ATP data is loaded into the first die scan chain register. This can result in more accurate at-speed path delay testing. At-speed testing can be particularly important with respect to high-speed devices where quantities such as signal propagation delay and resistance can vary significantly with increases in frequency. The test signals are thus propagated throughout the IC structure at-speed as opposed to at much lower speeds. Multi die testing in a packaged device is achieved looking at the whole packaged device and targeting each die under test by enabling and interconnecting pipeline stages in multiple tiles wherein the interconnected pipeline stages have individually configurable delay values depending on the di configured under test.

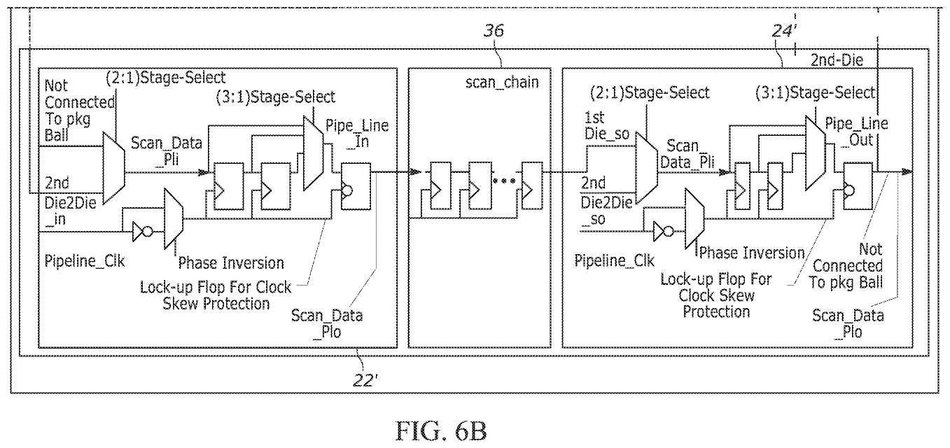

FIGS. 6A and 6B shows homogenous circuit dies 12, 14, respectively of a MCM, in accordance with some embodiments. The circuit dies 12 and 14 each have respectively reconfigurable input pipeline registers 22 and output pipeline registers 24, with a die-to-die interface interconnecting the input and output pipeline stages. In some embodiments, test equipment is connected to an input pin of the MCM. The test equipment transmits pipeline delay configuration data for a first die under test (DUT) to configure a first die input pipeline register 22 with a first delay value. The test equipment transmits the ATP data into a targeted die scan chain register on the first die in a predetermined number of clock cycles via the first delay value of the first die pipeline register. The first die is configured to perform a scan chain test of the with the ATP data. The test equipment transmits pipeline delay configuration data for a second DUT to configure the first die input pipeline register 22 with a second delay value, and transmits the ATP data into a second die scan chain register in the predetermined number of clock cycles via the reconfigured first die input pipeline register and the die-to-die interconnect. In some embodiments, the pipeline delay configuration data further includes data to configure a second die input pipeline register with a third delay value, and the ATP data is transmitted into the second die scan chain register via the second die input pipeline register. In such embodiments, the ATP scan data may propagate through the first die input pipeline register having the first delay value in the same amount of clock cycles as propagating through the first and second die input pipeline registers having the second and third delay values, respectively. ATPG vector testing of the MCM 10 using ATP testing may be used with lossless compression, e.g., 1:10 compression, in loading and configuring the test data.

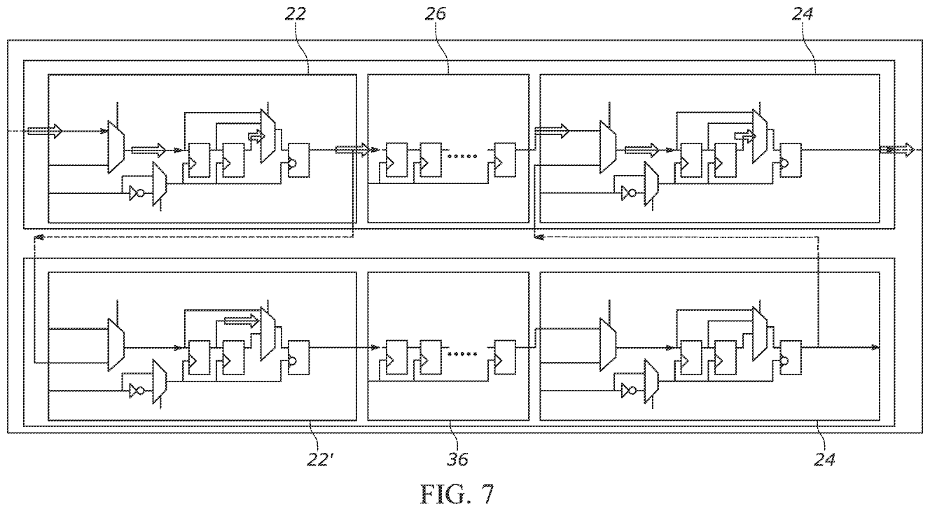

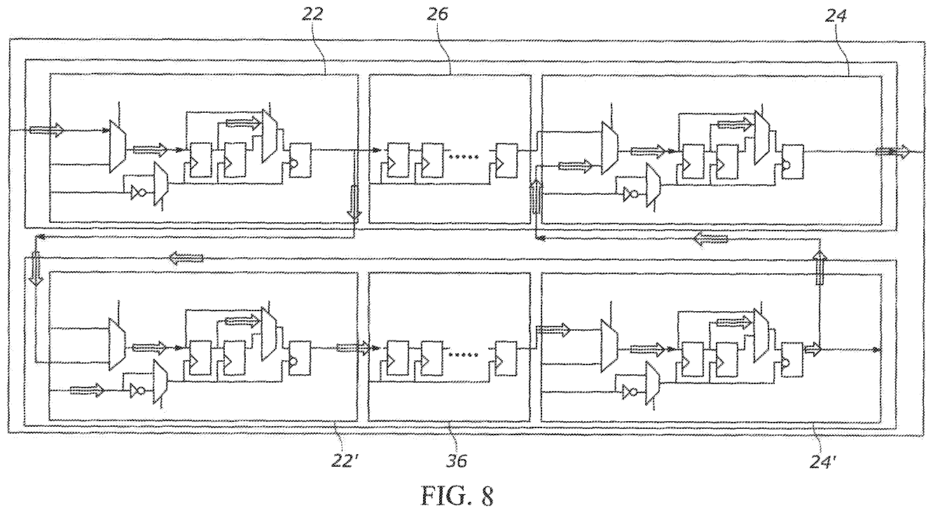

FIG. 7 illustrates a data path for loading ATP data into a first die scan chain register of a MCM having multiple homogenous circuit dies 12, 14, in accordance with some embodiments. The ATP data flow is indicated by arrows. Test equipment is connected to an input pin of the MCM and pipeline delay configuration data for a first DUT is transmitted to MCM to configure a first die input pipeline register with a first delay value, shown in FIG. 7 as two flip-flop stages. The pipeline delay configuration data for the first DUT may include a selection signal for the multiplexer connected to the plurality of output taps of the sequence of flip-flops. The ATP data is transmitted into the first die scan chain register, and the scan chain test is performed on the first die.

After the scan chain test, the results of the scan chain are shifted into the first die output pipeline register 24. Similar to the first die input pipeline register 22, the first die output pipeline register 24 is configurable to have a variable delay, shown in FIG. 7 as a similar sequence of flip-flops. The sequence of flip-flops have a plurality of output taps connected to a multiplexer. The pipeline delay configuration data transmitted into the MCM may similarly configure a selection signal for the multiplexer in the first die pipeline output register 24. In FIG. 7, the multiplexer in the first die pipeline output register 24 selects the output corresponding to a two-flip flop delay value. As described in more detail below, the configurable pipeline output registers in each circuit die may further ensure that the scan chain test results are seen at the output pin of the MCM after the same number of clock cycles, regardless of which circuit die is actively under test.

FIG. 8 illustrates a data path for loading ATP data into a second die scan chain register, in accordance with some embodiments. Pipeline delay configuration data is transmitted into the MCM via an input pin to configure the first and second input pipeline registers, 22 and 22′, respectively. Specifically, the first die input pipeline register 22 is configured with a second delay value corresponding to one pipeline flip-flop delay while second die input pipeline register 22′ is configured with a third delay value corresponding to one pipeline flip-flop delay. It should be noted that as each die is homogenous, each die thus includes input pipeline registers usable for configurable delay. Embodiments herein may extend to MCMs having inter-die interconnects between non-homogenous circuit dies, in which one input pipeline register may have a configurable delay value with delay value settings for a plurality of DUT settings. Similar to FIG. 7, the data path for ATP data through each pipeline flip-flop is indicated by an arrow. As shown, the ATP data is transmitted into the MCM via the input pin. The ATP data propagates through the first and second die input pipeline stages each having one flip-flop of delay. As described above, the shift mode frequency of the clock used by the flip-flops may be associated with the propagation delay between the output of the first die input pipeline register and the input of the second die input pipeline register 22′. Thusly altering the route that the ATP data takes so that the timing is the same regardless of which die is being tested, then the same exact pattern with same exact stored sequence and pattern can be read out from the same memory location of the test equipment, which translates to cost savings.

Similar to FIG. 7, the first and second circuit dies may contain pipeline output registers 24 and 24′, respectively. As described above, the first die pipeline output register 24 has a two flip-flop delay while the first circuit die was actively under test. The pipeline delay configuration data for the second DUT may include data to reconfigure the first die pipeline output register 24 to have a less (i.e., one flip-flop delay value), as additional output delay is incurred via the die-to-die interconnect when the second circuit die is actively under test. The pipeline delay configuration data configures the second die pipeline output register 24′ with a one flip-flop delay value. The scan chain results are output from the second die scan chain register into the second die pipeline output register 24′, which outputs the results to the first die pipeline output register 24 via die-to-die interconnect. As described above, the shift frequency is selected to ensure sufficient propagation time over the die-to-die interconnect. The number of flip flops in the above examples is purely illustrative, and should not be considered limiting.

Addressing ATPG Scan Pattern vector depth by reusing the same pattern set to test all tiles (or same dies) achieves higher ATPG scan shift mode frequency and reduces total test time of testing all tiles during production of packaged device with multiple tiles. Reusing the same pattern set irrespective of which tile is under test saves vector memory, thus lowering the packaged device test costs in production. Furthermore, pipeline stages in each homogenous circuit dies reduces the propagation delay between each successive flip-flop, and increases ATPG shift mode frequency (i.e., higher frequency, a shorter time-period) which in turn reduces the actual time spent to test each device. As described, the test pattern data route facilitates timing which is the same regardless of which die is being tested, The same ATP pattern set may be used in each circuit die by configuring the input delay for each pipeline stage based on which tile is actively under test in a multi-tile packaged device, as the number of shift vector cycles from the perspective of the testing equipment is same regardless of which circuit die is currently under test, e.g., if Vector Depth (VD)=60M Cycles and Shift-Frequency(F)=10 ns; then Time To Test Device(TT)=60M*10 ns=600 ms, and as follows:
Additional embodiment case 1: If the scan chain test is for 4 Tiles and the ATP is loaded into each tile using pipeline registers with configurable delays, then VD=60*4=240M, F=10 ns, TT=2.4 Sec;
Additional embodiment case 2: If the scan chain test is performed for 4 Tiles and the ATP is loaded into the tiles individually without pipeline registers, the shift frequency is reduced which increases the period between clock cycles to 40 ns. In such an embodiment, VD=60*4 =240M, F=40 ns, TT=2.4*4 Sec=9.6 Sec. The goal is to Increase Shift Frequency (F) and Reuse the Same pattern set for all 4-Tiles in Complex Case.

In these cases, VD=60M total, F=10 ns, TT=4*60*10=2.4 Sec; In the cases above, VD=60M which is independent of tiles. In case 1, the shift frequency F=10 ns, as compared to Case 2 above, which in which F=40 ns, because of the pipeline register stages.

In a further exemplary embodiment, one may utilize 4-tiles in a packaged device, thus by targeting to test a block with 500 as the scan chain length inside the design (tile). Adding 4 pipeline flops for the Scan-Data-In and 4 pipelines (PL) in Scan-Data-Out before shifting in/out scan data to the block under test in a tile which helps to accelerate scan shift mode frequency, where testing a block in a tile takes 500+4+4=508 as the length; 500 flops are coming from scan chain of the block under test, 4 flops coming in Scan data-In path, 4 flops in Scan-Data out path. The goal is to increase the shift mode frequency which is limited by I/O delay+routing delays in Scan-Data-in/out paths. By enabling pipelines stages one can overcome that and can increase the shift mode frequency. By assuming one pipeline minimum in each tile in scan-Data-in/out path helps to increase the frequency of shift mode ATPG patterns, one can look at the solution as follows. −4(PL/Tile0)+500(Tile0 block under test)+4(PL/Tile0)=>to test block in Tile0=Length (508 i.e. 508 vector cycles per pattern)−1(PL/Tile0)+3 (PL/Tile1)+500 (Tile1 block under test-same block as above but different die)+3 (PL/Tile1)+1(PL/Tile0)=>to test same block in Tile1=Length (508)−1(PL/Tile0)+1(PL/Tile1)+2 (PL/Tile2)+500 (Tile2 block under test-same block as above but different die)+2 (PL/Tile2)+1 (PL/Tile1)+1(PL/Tile0)=>to test same block in Tile2=Length (508)−1(PL/Tile0)+1(PL/Tile1)+1 (PL/Tile2)+1 (PL/Tile3)+500 (Tile2 block under test-same block as above but different die)+1 (PL/Tile3)+1 (PL/Tile2)+1 (PL/Tile1)+1(PL/Tile0)=>to test same block in Tile2=Length (508). By configuring mux and pipeline stages in each tile based on the tile which is under test before applying the ATPG patterns (which is large volume vector cycles), one may utilize use the same ATPG pattern set, and reduce shift-in/out time (high frequency of shift clock) since one can safely transfer the shift-data-in/out which in turn effects total test time. In the above example, to test one block in a tile it takes 508*10000 (i.e., pattern)*10 ns (=shift mode frequency)=508 ms, where the total test time depends on shift mode frequency. Embodiments described herein further reduce testing costs by re-utilizing the same ATPG patterns across the various homogeneous tiles.

One or more embodiments disclosed within this specification can be embodied in other forms without departing from the spirit or essential attributes thereof. Accordingly, reference should be made to the following claims, rather than to the foregoing specification, as indicating the scope of the one or more embodiments. One or more embodiments can be realized in hardware or a combination of hardware and software. One or more embodiments can be realized in a centralized fashion in one system or in a distributed fashion where different elements are spread across several interconnected systems. Any kind of data processing system or other apparatus adapted for carrying out at least a portion of the methods described herein is suited. It should be appreciated, however, that the one or more embodiments are merely exemplary. Therefore, specific structural and functional details disclosed within this specification are not to be interpreted as limiting, but merely as a basis for the claims and as a representative basis for teaching one skilled in the art to variously employ the one or more embodiments in virtually any appropriately detailed structure. Further, the terms and phrases used herein are not intended to be limiting, but rather to provide an understandable description of the one or more embodiments disclosed herein.

1. A method for testing a multi-chip-module (MCM) using an automated test pattern (ATP), the method comprising:
connecting test equipment to an input pin of the MCM;
transmitting pipeline delay configuration data for a first die-under-test (DUT) to configure a first die input pipeline register with a first delay value at a first die of the MCM;
transmitting ATP data into a first die scan chain register in a predetermined number of clock cycles via the first delay value of the first die input pipeline register;
configuring the first die to perform a scan chain test with the ATP data;
transmitting pipeline delay configuration data for a second DUT to configure the first die input pipeline register with a second delay value;
transmitting the ATP data into a second die scan chain register in the predetermined number of clock cycles via the reconfigured first die input pipeline register and a die-to-die interconnect; and
configuring the second die to perform a scan chain test with the ATP data.

2. The method of claim 1, wherein the transmitted pipeline delay configuration data for the first DUT configures multiplexing logic in the first die input pipeline register, the multiplexing logic applying the first delay value to the ATP data by selecting an output tap of a plurality of output taps.

3. The method of claim 1, wherein the transmitted pipeline configuration data for the second DUT further configures a second die input pipeline register with a third delay value, the second die input pipeline register in between the die-to-die interconnect and the second scan chain register.

4. The method of claim 1, further comprising transmitting a scan chain clock into the MCM via a clock input pin, the scan chain clock used to clock the first die input pipeline register and the first die scan chain register.

5. The method of claim 4, wherein the scan chain clock has a frequency associated with a propagation delay of the die-to-die interconnect.

6. The method of claim 1, wherein the transmitted pipeline delay configuration data for the first DUT further configures a first die output pipeline register on the first die based on the first delay value, and the transmitted pipeline delay configuration data for the second DUT further configures the first die output pipeline register on the first die based on the second delay value.

7. The method of claim 6, further comprising capturing a first scan chain result from the scan chain test on the first die from the first die output pipeline register, and capturing the a second scan chain result from the scan chain test on the second die from the first die output pipeline register, the first and second scan chain results each captured during a second predetermined number of clock cycles.

8. The method of claim 6, wherein the transmitted pipeline delay data for the first and second DUTs each include respective data to configure multiplexing logic in the first pipeline output register based on the first and second delay values, respectively.

9. The method of claim 8, wherein the multiplexing logic selects an output tap of a plurality of output taps of the first pipeline output register based on the first and second delay values, respectively.

10. The method of claim 1, further comprising:
transmitting pipeline configuration data for a third DUT into the MCM to reconfigure the first die input pipeline register with a third delay value and a second die input pipeline register with a fourth delay value;
loading the ATP data into a third die scan chain register in the predetermined number of clock cycles via the reconfigured first die input pipeline register, the second die input pipeline register, and a die-to-die interconnect between the second and third circuit dies; and
configuring the third die to perform a scan chain test with the ATP data.

11. A method for testing a multi-chip-module (MCM) using an automated test pattern (ATP), the method comprising:
configuring a first timing delay of a first data path from an MCM input pin to a first die-under-test (DUT) by adjusting a delay of at least a first pipeline register with a first delay value at a first die of the MCM;
loading an ATP data sequence through the first pipeline register to a scan chain register of the first DUT;
performing a scan chain test of the first DUT;
configuring a second timing delay of a second data path from the input pin of the MCM through the at least first pipeline register to a second DUT by readjusting the delay of the first pipeline register; and
loading the ATP data sequence to a scan chain register of the second DUT; and
performing a scan chain test of the second DUT.

12. The method as recited in claim 11, wherein the first die and the second die are homogenous, with the ATP data being applied to the first die scan chain register, having the same ATP data being applied the second die scan chain register according to a defined timing pattern.

13. The method as recited in claim 12, wherein the second timing delay configuring step comprises setting a programable delay by adjusting the delay of the first pipeline register to apply the same ATP data to the second die scan chain register according to the same defined timing pattern.

14. The method as recited in claim 12, wherein the second timing delay configuring step comprises reducing the delay of the first pipeline register to apply the same ATP data to the second die scan chain register according to the same defined timing pattern.

15. The method as recited in claim 11, wherein the ATP data comprises a defined Automatic Test Pattern Generation (ATPG) data pattern.

16. The method as recited in claim 11, further comprising providing a scan pattern router of the first die connected to the first die input pipeline register, wherein the loading step comprises using the scan pattern router to load the first die scan chain register according to the ATP data having a defined timing pattern to adjust the delay of the first die pipeline register and route ATP sequence data to a second die.

17. The method as recited in claim 16, receiving a retransmission of the ATP sequence data at the first die and forwarding the retransmitted ATP sequence data through the first die pipeline register and through the scan router to a second die according to the defined timing pattern.

18. A multi-chip-module (MCM) test equipment method comprising:
configuring a first die input pipeline register at a first die in the MCM with a first delay value with a command from the test equipment;
issuing an automated test pattern (ATP) from the test equipment to load ATP data into a first die scan chain register in a predetermined number of clock cycles via the first delay value of the first die pipeline register;
performing a scan chain test of the first die with the ATP data using a read path to the test equipment;
configuring the first die input pipeline register with a second delay value;
providing a die-to-die interconnect from the first die to a second die of the MCM;
loading the ATP data into the second die scan chain register in the predetermined number of clock cycles via the second delay value of the first die pipeline register and the die-to-die interconnect; and
performing a scan chain test of the second die using the read path to the test equipment.

19. The method as recited in claim 18, further comprising ATP data scan pattern routing of the first die connecting the first die input pipeline register with the second die input pipeline register, with the command from the test equipment reconfiguring the die-to-die interconnect providing step from the first die to the second die of the MCM to load the same ATP data to the second die scan chain register as the loading of the first die scan chain register with the same predetermined number of clock cycles.

20. The method as recited in claim 19, receiving a retransmission of the ATP sequence data at the first die forwarded with the ATP data scan pattern routing to sequence data through the first die pipeline register to a second die according to a defined timing pattern.

21. (canceled)
